(19) United States
(12) Patent Application Publication
(10) Pub. No.: US 2017/0059324 A1
(43) Pub. Date: Mar. 2, 2017

(54) METHOD FOR CALCULATING THE ANGLE OF INCLINATION OF MAGNETIC FIELD IN A SENSOR COORDINATION SYSTEM

(71) Applicant: Magnachip Semiconductor, Ltd., Cheongju-si (KR)

(72) Inventors: Dong Yoon KIM, Ithaca, NY (US); Byung Ki KIM, Seongnam-si (KR); Seung Hwan PARK, Sejong-si (KR); Kyoung Suck KI, Cheongju-si (KR); Hyung Sik SHIN, Seoul (KR); Jo An NA, Seoul (KR); Young Joon KIM, Seoul (KR); Yeon Soo CHOI, Seongnam-si (KR)

(73) Assignee: Magnachip Semiconductor, Ltd., Cheongju-si (KR)

(21) Appl. No.: 15/132,545

(22) Filed: Apr. 19, 2016

(30) Foreign Application Priority Data
Aug. 26, 2015 (KR) 10-2015-0120474

(51) Int. Cl. G01C 19/5776; G01R 33/02; G01P 15/18; G06F 17/16; G01C 17/02

(52) U.S. Cl. CPC G01C 19/5776; G06F 17/16; G01C 17/02; G01P 15/18; G01R 33/0206

(57) ABSTRACT

A method for calculating an angle of inclination of a magnetic field in a sensor coordination system includes measuring a magnetic field vector using a magnetometer, measuring an acceleration vector using an accelerometer, determining whether the sensor coordination system is in a moving state or a stationary state using the acceleration vector, and calculating the inclination angle of the magnetic field using the magnetic field vector and the acceleration vector, in response to the determining indicating the stationary state.

### CROSS-REFERENCE TO RELATED APPLICATION(S)

This application claims the benefit under 35 USC 119(a) of Korean Patent Application No. 10-2015-0120474 filed on Aug. 26, 2015 in the Korean Intellectual Property Office, the entire disclosure of which is incorporated herein by reference for all purposes.

### BACKGROUND

1. Field

The following description relates to a method for calculating the angle of inclination of a magnetic field line. The following description also relates to an apparatus using such a method. The following description also relates to a method for calculating an accurate angle of inclination with regard to three-dimensional magnetic field information in accordance with a horizontal plane.

2. Description of Related Art

In general, a magnetic field is generated by an interaction between a magnet and a current flowing near the magnet. Furthermore, such a magnetic field is oriented in a space towards a predetermined direction in three dimensions. For example, a magnetic field may be measure to correspond to the interaction of the magnetic field and electric field, which induces magnetic forces that pull and push various kinds of metals.

Such principles are applied to various electric motors and electric generators in various fields and applications. However, a majority of such applications convert the magnetic force into electric power. Additionally, information regarding the direction of the magnetic field is not significant in these applications. Rather, the intensity of the magnetic intensity is more relevant in such examples.

As smartphones are becoming more and more popular, an electric compass is widely used. Even GPS for an automobile adapts an electric compass for more accurate heading angle information. In addition, direction information of such a magnetic field is playing a critical role in providing augmented reality functionality.

Compass applications widely relate to a two-dimensional application, regardless of an inclination angle of a magnetic field. In other words, the inclination angle is not measured since the heading angle is calculated in accordance with the magnetic north. In general applications, an inclination angle is measured based on a geological Earth model. In such an approach, the inclination has a fixed value, which represents the accurate inclination angle. The intensity of a geological magnetic field is the range of 20-70 μT. The intensity varies according to the location where it is measured, that is, it increases at the equator and close to the Earth's surface. The geomagnetic field may be interpreted based on the dipole model, which supposes a magnetic dipole at the center of Earth. The magnetic field points from the South Pole to North Pole. The magnetic field line may be interpreted as a reference of a heading angle. Although a disturbance may occur, such a disturbance is seemingly temporary. Thus, the magnetic field line becomes standardized to a certain degree. The intensity of a magnetic field and its inclination angle or declination angle is able to be calculated through the Earth magnetic field model based on the current location from which the magnetic field is measured. Such a magnetic field established by a model of the Earth is applicable to geological research.

However, a compass application of measuring a magnetic field is a two-dimensional application regardless of the inclination angle of a magnetic field. In other words, the inclination angle information is not reflected in the compass measurement because a two-dimensional angle is calculated in accordance with just the magnetic North, without an inclination component.

Recently, as micro-electro mechanical system (MEMS) technology develops, the packaging of MEMS sensors such as a magnetometer, an accelerometer, and a gyroscope has been shrinking rapidly and the price is decreasing due to mass production. These sensors became default sensors in the exploding smartphone market, such that the sensors are expected components of a smartphone. Accordingly, sensor fusion technology using different types of sensors, such as these MEMS sensors is being developed. The usefulness of accurate information about the inclination angle of a magnetic field is increasing in this fast growing industry of portable electronics. In this particular market, successful interaction with users such as a game controller is important. For example, an inclination angle of a magnetic field is potentially extremely helpful angle information used to calculate an accurate angle within 3D space. In general, information regarding an accurate inclination angle is required for providing an absolute heading angle.

Furthermore, in an alternative technology, three-dimensional magnetic field information is also used, by using horizontal inclination information that is provided by the geological Earth model. However, some related arts use a value having a predetermined constant value, which is fixed according to geological locations. Accordingly, accurate geomagnetic information is not provided in a case of disturbance from the circumstances used for providing the predetermined constant value.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a method for calculating an angle of inclination of a magnetic field in a sensor coordination system includes measuring a magnetic field vector using a magnetometer, measuring an acceleration vector using an accelerometer, determining whether the sensor coordination system is in a moving state or a stationary state using the acceleration vector, and calculating the inclination angle of the magnetic field using the magnetic field vector and the acceleration vector, in response to the sensor coordinate system being determined to be in the stationary state.

The acceleration vector comprises a gravitational acceleration component and a linear acceleration component.

The sensor coordination system is determined to be in the stationary state in response to a following Equation being satisfied: |∥Acc∥−a_{g}|≦Tsᵥₐₗᵤₑ, wherein a_{g}, Acc and Tsᵥₐₗᵤₑ denote a gravitational acceleration value, a sensed acceleration vector, and a threshold value, respectively.

The acceleration vector may have as its value a moving average value vector that is a moving average value regarding a size value of an number N of acceleration vectors according to a following Equation:

$${Acc}_{mean} = \frac{{\sum }_{i = 1}^{N} ‖ {Acc}_{i} ‖}{N} ,$$

wherein Accₘₑₐₙ is the moving average value vector and each Accᵢ is an i^{th} acceleration vector.

The threshold value may be a fixed value or a variance value regarding a number N of latest measured acceleration vectors that is calculated according to a following Equation:

$${σ}_{Acc} = \sqrt{\frac{{\sum }_{i = 1}^{N} {( ‖ {Acc}_{i} ‖ - {Acc}_{mean} )}^{2}}{N}} ,$$

wherein σ_{Acc} is the variance value and each Accᵢ is an i^{th} acceleration vector.

The inclination angle of the magnetic field may be calculated by a following Equation: θ=π/2−sin⁻¹(|n_{g}×nₘ|), wherein θ denotes the angle of inclination of the magnetic field, nₘ denotes the magnetic field vector, and n_{g} denotes the acceleration vector.

The inclination angle of the magnetic field may be calculated by a following Equation: θ=π/2−cos⁻¹(n_{g}·nₘ), wherein θ denotes the angle of inclination of the magnetic field, nₘ denotes the magnetic field vector, and n_{g} denotes the acceleration vector.

The sensor coordination system may include the magnetometer and the accelerometer.

The method may further comprise using a previously calculated inclination angle of the magnetic field as an estimate of the inclination angle of the magnetic field, in response to the sensor coordinate system being determined to be in the moving state.

In one general aspect, an apparatus for calculating an angle of inclination of a magnetic field includes a magnetic sensor configured to measure a magnetic sensor vector, an accelerometer sensor configured to measure an acceleration vector, a moving state determiner configured to determine whether the apparatus is in a moving state or a stationary state using the acceleration vector, and an inclination angle calculator configured to calculate the inclination angle of the magnetic field using the magnetic vector and the acceleration vector, in response to determining that the apparatus is in a stationary state.

The acceleration vector may include a gravitational acceleration component and a linear acceleration component.

The moving state determiner may be configured to determine the stationary state in response to a following equation being satisfied |∥Acc∥−a_{g}|≦Tsᵥₐₗᵤₑ, wherein a_{g}, Acc and Tsᵥₐₗᵤₑ denote a gravitational acceleration value, a sensed acceleration vector and a threshold value, respectively.

The acceleration vector may have as its value a moving average value vector that is a moving average value regarding a size value of a number N of acceleration vectors according to a following Equation:

$${Acc}_{mean} = \frac{{\sum }_{i = 1}^{N} ‖ {Acc}_{i} ‖}{N} ,$$

wherein Accₘₑₐₙ is the moving average value vector and each Accᵢ is an i^{th} acceleration vector.

The threshold value may have a fixed value or a variance regarding a number N of latest measured acceleration vectors that is calculated according to the following Equation:

$${σ}_{Acc} = \sqrt{\frac{{\sum }_{i = 1}^{N} {( ‖ {Acc}_{i} ‖ - {Acc}_{mean} )}^{2}}{N}} ,$$

wherein σ_{Acc} is the variance value and each Accᵢ is an i^{th} acceleration vector.

The inclination angle of the magnetic field may be calculated using the following equation: θ=π/2−sin⁻¹(|n_{g}×nₘ|), wherein θ denotes the angle of inclination of the magnetic field, nₘ denotes the magnetic field vector, and n_{g} denotes the acceleration vector.

The inclination angle of the magnetic field may be calculated using the following equation: θ=π/2−cos⁻¹(n_{g}·nₘ), wherein θ denotes the angle of inclination of the magnetic field, nₘ denotes the magnetic field vector, and n_{g} denotes the acceleration vector.

The inclination calculator may use a previously calculated inclination angle of the magnetic field as an estimate of the inclination angle of the magnetic field, in response to determining that the apparatus is in the moving state.

Other features and aspects will be apparent from the following detailed description, the drawings, and the claims.

### BRIEF DESCRIPTION OF THE DRAWINGS

FIG. 1 is a diagram illustrating a relationship between gravity and an inclination angle.

FIG. 2 shows a measured magnetic field that varies according to a disturbance and a position of a sensor coordination system.

FIG. 3 shows a method for calculating an inclination angle of the magnetic field according to an embodiment.

FIG. 4 is a diagram geometrically illustrating a cross product of an accelerometer measurement vector n_{g} and a magnetometer measurement vector nₘ.

FIG. 5 is a diagram illustrating a method for calculating an inclination angle of a magnetic field according to an embodiment.

FIG. 6 is a diagram illustrating a calculation process of an inclination angle.

FIG. 7 is a diagram of an apparatus for calculating an inclination angle of a magnetic field according to an embodiment.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Certain examples are now described in greater detail with reference to the accompanying drawings. In the following description, the same drawing reference numerals are used for the same elements, even in different drawings. The matters defined in the description, such as detailed constructions of terms and elements, are provided to assist in a comprehensive understanding of the present examples. Accordingly, it is apparent that it is possible for the examples to be carried out without those specifically defined matters. Also, well-known functions or constructions are not described in detail to avoid obscuring the examples with unnecessary detail.

While the expressions such as “first” or “second” are potentially used to refer to various elements, the elements are not intended to be limited by the expressions. Such expressions are used only for the purpose of distinguishing one element from the other when referring to such elements.

The expressions presented are used herein only for the purpose of explaining specific examples and are not intended to place limits on the present examples. An expression in singular form also encompasses plural meaning, unless otherwise specified. Throughout the description, the expression “comprise” or “have” is used only to designate the existence of a characteristic, number, step, operation, element, component or a combination thereof which is described herein, but not to preclude possibility of existence of one or more of the other characteristics, numbers, steps, operations, elements, components or combinations of these or other appropriate additions.

Spatial words, such as below, beneath, lower, above and upper are used to conveniently recite a correlation between one element or features with respect to other elements or features, as illustrated in the drawings. When spatial terminology is used as referring to a direction as illustrated in the drawing, if the illustrated element is upside down, the element that was recited as below and beneath is also potentially considered to be above or on top of another element. Thus, examples presented below include all such instances related to the directions of below and above. An element is also potentially aligned in another direction, and in such examples, spatial words are interpreted according to the alignment.

The present disclosure is described more fully subsequently with reference to the accompanying drawings, in which embodiments are shown and described further.

The embodiments provide a method for calculating an inclination angle of a magnetic field with disturbance accurately represented when a surrounding disturbance is generated or when a sensor coordination system is not located horizontally on a horizontal plane.

In particular, the embodiments relate to a method for calculating an inclination angle of a magnetic field with disturbance accurately represented and an apparatus adopting such a method, which improves accuracy of magnetic field inclination angle measurement by determining a moving state of the sensor coordination system using accelerometer information and calculating inclination angle information based on the determination result.

Hereinafter, the technical expression, a magnetic field, which is used in the present disclosure, refers to a magnetic field with a disturbance included, unless stated otherwise.

A method for calculating the angle of inclination of a magnetic field and apparatus using the method according to an embodiment calculates an inclination angle of an accurate magnetic field based measurements of a magnetic sensor and an accelerometer.

Thereby, the embodiments are potentially used for realizing a virtual gyroscope using a combination of an acceleration sensor and a magnetic sensor. In particular, the embodiments are able to extract an angle and an angular velocity of an object in a three-dimensional space without using a physical gyroscope. Also, embodiments are able to improve a degree of precision when calculating the angle and angular velocity of the object.

Furthermore, the embodiments are potentially advantageous in providing accurate information for compass even in a device having an inclined position with a random or arbitrary angle that is not level.

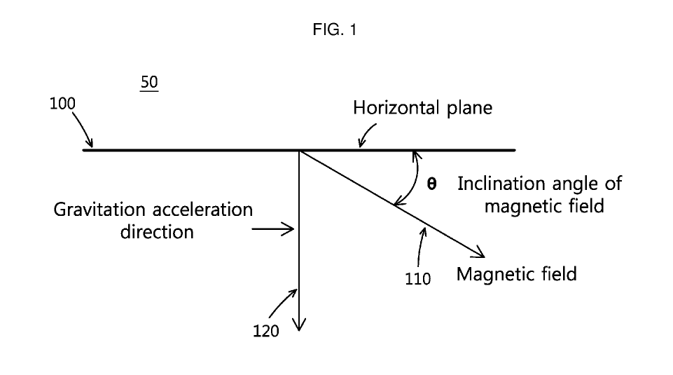

FIG. 1 is a diagram illustrating an inclination angle θ, a gravitation acceleration direction 120 and a magnetic field line 110 with respect to the horizontal plane 100. Acceleration due to gravity is a vector, which means it has both a magnitude and a direction.

As illustrated in the example of FIG. 1, a sensor coordination system 50 includes two sensors. The first sensor is a three-axis magnetometer and the second sensor is a three-axis accelerometer. The gravitational acceleration direction 120 is perpendicular to the horizontal plane 100 if the sensor coordination system 50 is level 100 and there is no magnetic disturbance or acceleration affecting the sensor coordination system 50. In this example, the magnetometer, or first sensor, measures a magnetic field line 110 that depends on a location of the sensor coordination system 50 on Earth. The magnetic line of force or magnetic field line 110 is oriented towards magnetic North and it points to the Earth's center, crossing the horizontal plane at the inclination angle θ in the Northern Hemisphere. The accelerometer, or second sensor, measures a gravitational acceleration direction 120 when there is no motion of the object 50 or the object 50 is in motion with a constant velocity.

Further, referring to FIG. 1, assuming a case of no acceleration indicates the object 50 is in still or, if it moves in a constant velocity thereby, no acceleration is generated. Herein, an accelerometer measures acceleration information of only the gravitational direction 120.

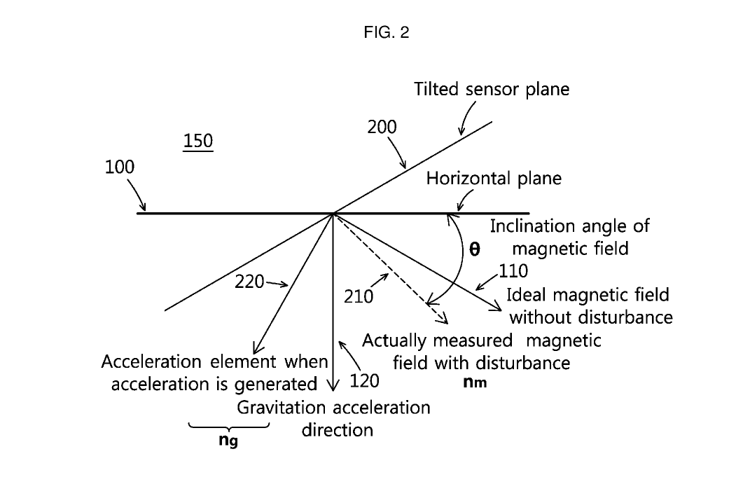

FIG. 1 illustrates an example in which a sensor coordination system is level 100 and without a magnetic disturbance, which is an ideal case, in that factors that make measurement harder are minimized. However, in an actual example, an outside disturbance possibly occurs and it disturbs operation of the sensor coordination system. Thus, inclination information 8 between the actually measured magnetic field line 210 and tilted sensor plane 200 differs from the ideal case. Hereinafter, these factors of an actual use case are illustrated with reference to the example of FIG. 2.

FIG. 2 shows a new magnetic field line 210 that is influenced by the disturbance. As illustrated in the example of FIG. 2, a tilted sensor plane 200 with respect to the sensor coordination system 150 is tilted with respect to the ideal horizontal plane 100. The tilt of tilted sensor plane 200 also implies that the sensor coordination system 150 moves with a linear acceleration. In this example, also, the magnetic field line 210 has a different direction from the ideal magnetic field line 110 due to a surrounding disturbance. The linear acceleration 220 also has a different direction from the gravitational acceleration 210.

In this example, an embodiment provides a method for calculating an inclination angle θ between the tilted sensor plane 200 and the measured magnetic field line 210 affected by a disturbance in the sensor coordination system 150.

The various kinds of disturbances exist in various settings. For example, when a speaker itself is the source of magnetic disturbance up to several Gauss, as a measure of magnetic field strength, and thus such magnet disturbance is easily hundreds to thousands times of the field strength of a geomagnetic field. And there are various other sources of disturbances not only around such electronic devices that explicitly include magnets but also a power line and WIFI line and so on, in that electronic devices generate electromagnetic fields as part of their operation. Further, metal also distorts and changes a magnetic field. Various metal products such as steel-framed structures, for example, vehicles are also included in this category. Thus, if such disturbance is not managed effectively, a global magnetic field is no longer useful as a reference because all of the other types of disturbance prevent reliable measures of the global magnetic field.

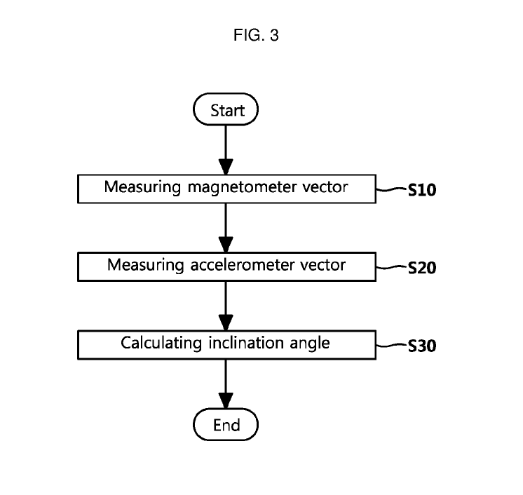

Hereinafter, a driving method according to the present embodiments is illustrated in the examples of FIGS. 3 to 7.

FIG. 3 shows a method for calculating the inclination angle of the magnetic field according to an embodiment.

As illustrated in the example of FIG. 3, the method for calculating an inclination angle of a magnetic field includes measuring first magnetic vector information nₘ in step S10, measuring second acceleration vector information n_{g} in step S20, and calculating an inclination angle of a magnetic field using the two measured vectors in step S30.

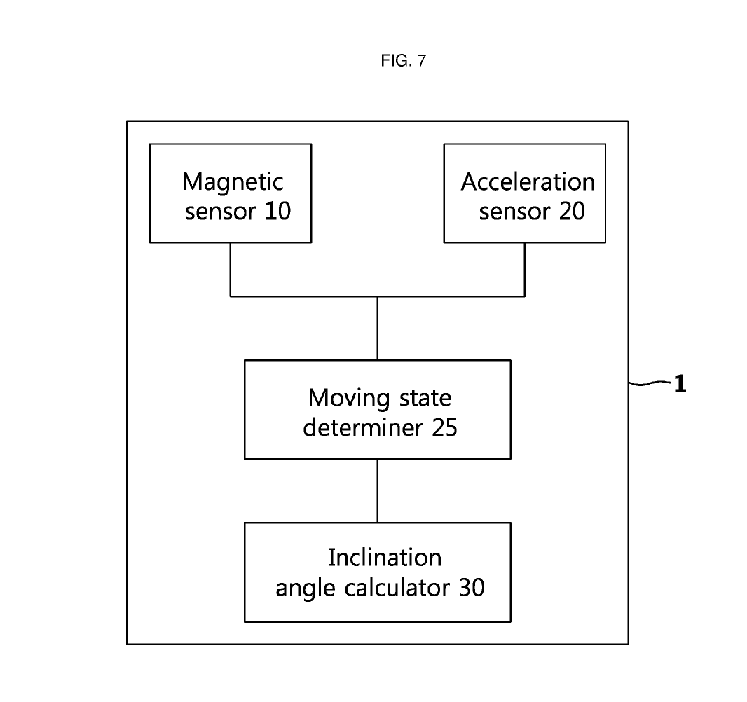

First, in step S10, the method measures the magnetic field vector information nₘ. For this step, a magnetic sensor is able be used to perform the measurement. For example, a magnetic sensor unit or magnetic sensor 10 of FIG. 7 is used to perform the measurement.

In general, the magnetic field intensity depends upon a user position or a position of the magnetic sensor. The magnetic field intensity herein is referred to as M₀ (μT). The magnetic field intensity herein is acquired as expressed in Equation 1 and 2, as follows:

M(t)=[Mₓ M_{y} M_{z}]μT Equation 1

M₀=\sqrt{Mₓ²+M_{y}²+M_{z}²} Equation 2

M(t) denotes a magnetic field intensity at a specific time, t. Mₓ, M_{y}, M_{z} herein refer to an output value of measured magnetic field intensity measured by the magnetic sensor in terms of x-axis, y-axis, and z-axis components, respectively. Here, a μT is a micro Tesla, used as a magnetic field intensity unit. The micro-tesla (μT) is a unit of measurement of the strength of the magnetic field, where the Tesla or T is the SI unit used to measure a magnetic field's strength.

Next, in step S20, the method measures acceleration vector information n_{g}. For this measurement, the acceleration sensor or accelerometer is used. For example, the acceleration sensor unit or acceleration sensor 20 of FIG. 7 is used. Here, an accelerometer is a device that measures acceleration, produced by the gravitational force or “g-force” acting upon an object. In general, all objects have approximately the same gravitational acceleration at a given location because the gravitational force is directly proportional to the mass of the objects that gravitationally attract each other, and hence the acceleration is the same for any object with respect to the Earth at a given point in space. Acceleration vector information n_{g} includes linear acceleration, which is related to the motion of the object itself and a gravitational acceleration a_{g}. Acceleration Acc is a vector quantity. The sensed acceleration vector magnitude is referred to as acceleration ∥Acc∥. Step S20 measures acceleration, including linear acceleration and gravitational acceleration a_{g}, by using the accelerometer. In physics, gravitational acceleration is the acceleration on an object caused by the force of gravitation. Gravitational acceleration g or a_{g} is an expression used in physics to indicate the intensity of a gravitational field. It is expressed in units of meters per second squared (m/s²). At the surface of the earth, 1 g is about 9.8 m/s². Thus, the measured acceleration information nₐ includes linear acceleration and gravitational acceleration a_{g}.

Generally, a gravitational direction does not change and always is directed to the center of the Earth. Hence, the gravitational acceleration is an element of the acceleration that can be detected when the accelerometer is stationary, in other words when there is no additional linear acceleration.

The output of an accelerometer as presented herein is a gravitational acceleration 9.8 m/s² that is able to be expressed in a vector form. In general, when the sensor coordination system is level 100, and when there is not acceleration, the acceleration, Acc(t) is acquired as expressed in Equation 3 as follows:

Acc(t)=a_{g}*[0 0 1] m/sec² Equation 3

Here, a_{g} denotes a gravitational acceleration, which generally has a value of 9.8 m/s². The acceleration, Acc(t) denotes a sum of linear acceleration and gravitational acceleration a_{g}. However, when the sensor coordination system is not level 100, the acceleration can be acquired as expressed in Equation 4, as follows:

Acc(t)=[Aₓ A_{y} A_{z}] m/sec² Equation 4

In Equation 4, Aₓ, A_{y}, A_{z} refer to accelerations with respect to x-axis, y-axis, and z-axis components respectively.

In step S30, the method calculates an inclination angle of magnetic field using the magnetic field vector information nₘ and acceleration vector information n_{g} that are measured through the step S10 and the step S20.

Ideally, if the sensor coordination system according to the present disclosure is level and there is no linear acceleration applied to the sensor coordination system, only an element of z-axis is left in the acceleration vector, as shown in Equation 4. Further, if a Y-axis of the magnetic sensor is oriented to correspond to magnetic north, the inclination angle θ of the magnetic field is able to be acquired as expressed in Equation 5, without magnetic field vector information nₘ and acceleration vector information n_{g}. The way in which inclination angle θ is able to be acquired as expressed in Equation 6 as follows:

$$θ = {tan}^{- 1} ( \frac{{M}_{z}}{{M}_{y}} ) \qquad Equation 5$$

$$θ = {tan}^{- 1} ( \frac{{M}_{z}}{\sqrt{{M}_{x}^{2} + {M}_{y}^{2}}} ) \qquad Equation 6$$

Herein, Mₓ, M_{y}, and M_{z} refers to the magnetic field intensity of x, y, and z respectively.

However, in an actual environment, the sensor coordination system is not always level 100 and if a disturbance occurs as shown in FIG. 2, Equations 5 or 6 alone are not able to be used to calculate the inclination angle of the magnetic field.

Accordingly, if a disturbance occurs, it is required that the inclination angle is calculated using the magnetic field vector information nₘ and acceleration vector information n_{g}. Hereinafter, such a method for calculating the inclination angle is illustrated.

First, the acceleration vector information n_{g} and magnetic field vector information nₘ are each acquired as expressed in Equations 7 and 8, respectively as follows:

n_{g}=(Aₓi+A_{y}j+A_{z}k)/∥Aₓi+A_{y}j+A_{z}k∥ Equation 7

nₘ=(Mₓi+M_{y}j+M_{z}k)/∥Mₓi+M_{y}j+M_{z}k∥ Equation 8

Herein, i, j, and k each refer to a unit vector for axes x, y and z, respectively. Also, it is assumed that the two sensor coordinates coincide.

Herein, a cross product of n_{g} and nₘ is acquired as expressed in Equation 9 and Equation 10 as follows:

$$\begin{matrix}{n}_{g} {n}_{m} = \frac{( {A}_{x} i + {A}_{y} j + {A}_{z} k )}{‖ {A}_{x} i + {A}_{y} j + {A}_{z} k ‖} \frac{( {M}_{x} i + {M}_{y} j + {M}_{z} k )}{‖ {M}_{x} i + {M}_{y} j + {M}_{z} k ‖} & Equation 9 \\ {n}_{g} {n}_{m} = \frac{[ \begin{matrix}( {A}_{y} {M}_{z} - {A}_{z} {M}_{y} ) i + \\ ( {A}_{z} {M}_{x} - {A}_{x} {M}_{z} ) j + ( {A}_{x} {M}_{y} - {A}_{y} {M}_{x} ) k\end{matrix} ]}{{A}_{o} {M}_{o}} & Equation 10\end{matrix}$$

In Equation 9, Aₓ, A_{y}, and A_{z} refer to the magnitude of an acceleration and they include both the linear acceleration portion and gravitational acceleration 9.8 m/sec².

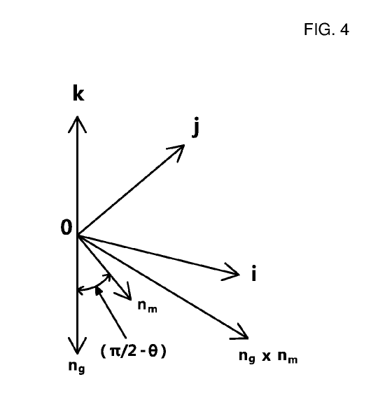

The cross product thereof is illustrated in FIG. 4 as expressed geometrically. Referring to the example of FIG. 4, vector information regarding the acceleration vector information n_{g} and the magnetic field vector information nₘ and cross product n_{g}×nₘ are shown. The acceleration vector information n_{g} is perpendicular to the horizontal plane. The angle between n_{g} and nₘ is (π/2)−θ. Herein, i, j, k refers to unit vectors of x, y and z directions, respectively.

As illustrated in the example of FIG. 1, if there is no additional acceleration other than gravitational acceleration in the sensor apparatus according to the present disclosure, the acceleration vector information n_{g} that is measured through the step S20 corresponds with the horizontal direction that is perpendicular to the horizontal plane.

Accordingly, the present embodiments presume that the acceleration vector information n_{g} coincides with the gravitational direction. The acceleration vector information n_{g} is thus used as a reference value to calculate the inclination angle of the magnetic vector information nₘ accordingly.

Thus, according to an embodiment, the inclination angle of the magnetic field is calculated based on a cross product between the magnetic field vector information nₘ and the acceleration vector information n_{g} in the step S30. The particular inclination angle is thus acquired as expressed in Equation 11 and Equation 12 as follows:

θ=π/2−sin⁻¹(|n_{g}×nₘ|) Equation 11

Here, θ denotes an inclination angle of a magnetic field.

$$θ = \frac{π}{2} - {sin}^{- 1} ( \frac{( {A}_{x} i + {A}_{y} j + {A}_{z} k )}{‖ {A}_{x} i + {A}_{y} j + {A}_{z} k ‖} \frac{( {M}_{x} i + {M}_{y} j + {M}_{z} k )}{‖ {M}_{x} i + {M}_{y} j + {M}_{z} k ‖} ) \qquad Equation 12$$

In particular, it is understood that there is a vector a and a vector b. An angle between the vectors a and b refers to θₐ Here, the magnitude of a cross product between vector a and vector b is |a|*|b|*sin θₐ. The angle between the vectors a and b is extracted using the above Equation 12. Hereinafter, as shown in FIG. 1 and FIG. 2, supposing that the acceleration vector information n_{g} is oriented towards the same direction as the gravitational direction, then Equation 12 can be acquired, referring to an assumption that the acceleration vector information n_{g} and the horizontal plane are perpendicular to each other as shown in FIG. 1.

According to another embodiment, in step S30, an inclination angle of a magnetic field is calculated through an inner product between the magnetic field vector information nₘ and acceleration vector information n_{g}. For example, a particular horizontal inclination angle is acquired as expressed in Equation 13 and 14 as follows:

θ=π/2−cos⁻¹(n_{g}·nₘ) Equation 13

Here, θ refers to the inclination angle of the magnetic field.

$$θ = \frac{π}{2} - {cos}^{- 1} ( \frac{{A}_{x} {M}_{x} + {A}_{y} {M}_{y} + {A}_{z} {M}_{z}}{‖ {A}_{x} i + {A}_{y} j + {A}_{z} k ‖ ‖ {M}_{x} i + {M}_{y} j + {M}_{z} k ‖} ) \qquad Equation 14$$

In particular, there is vector a and vector b. The angle between the vectors a and b refers to θ_{b}. Herein, the magnitude of the inner product between vector and b is |a|*|b|*sin θ_{b}. The angle between the vector a and vector b is extracted by using Equation 14. Hereinafter, as shown in FIG. 1 and FIG. 2, supposing that the acceleration vector information n_{g} is oriented towards the same direction as the gravity, Equation 14 can be acquired, implying that the acceleration vector information n_{g} and the horizontal plane are perpendicular to each other.

However, a physical value that is actually measured through the accelerometer sensor, not only measures the value of gravitational acceleration but also the linear acceleration. The linear acceleration plays a role of noise adding difficulty to deriving the inclination angle. In other words, when a sensor apparatus moves with a certain linear acceleration, an inclination angle is not able to be extracted accurately easily because the accelerometer generates a linear acceleration in addition to gravitational acceleration.

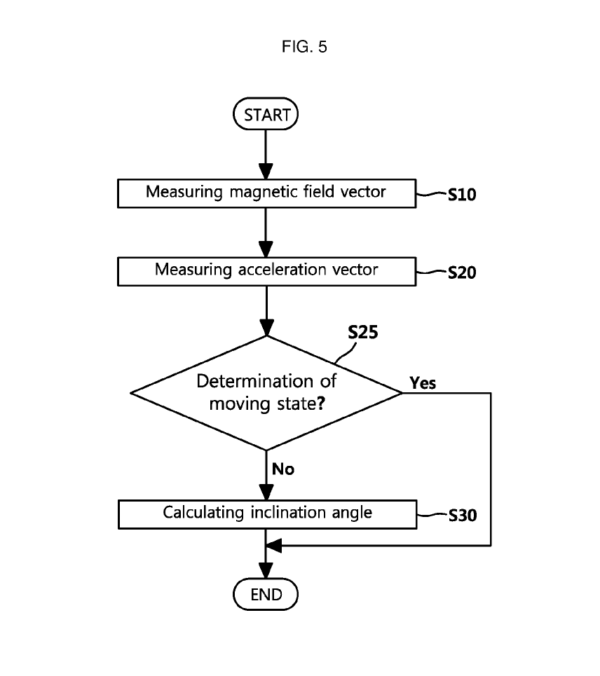

Accordingly, an embodiment provides a method for calculating a more accurate inclination angle by limiting calculations in the derivation of an inclination angle, according to a sensor value that is measured through the accelerometer sensor. Hereinafter, such a method is illustrated with reference to FIG. 5.

FIG. 5 is a diagram illustrating a method for calculating an inclination angle of a magnetic field according to an embodiment.

As illustrated in FIG. 5, a method for calculating an inclination angle of a magnetic field according to the present description further includes determining a moving state in step S25 and may include calculation of an inclination angle of the magnetic field in a case that is determined to be a stationary state in step S25.

In other words, when determined to be a moving state through the performance of step S25, the prior horizontal inclination value is used without calculating a new horizontal inclination value.

A method for determining a moving state of the S25 is applied with various method steps as follows.

First, determining a moving state considers comparison of magnitude of the measured acceleration vector.

According to an embodiment, in step S25, when the difference between the magnitude of an acceleration vector Acc and a gravitational acceleration value a_{g} that are measured in step S20 when measuring an acceleration vector information n_{g}, is less than a threshold value Tsᵥₐₗᵤₑ, it is determined to be a stationary state. This information is acquired as expressed in Equation 15 and 16, as follows:

∥Accᵢ∥=\sqrt{Aₓ_{ᵢ}²+A_{y}_{ᵢ}²+Aₓ_{ᵢ}²} Equation 15

In Equation 15, Accᵢ refers to a i^{th} acceleration.

|∥Acc∥−a_{g}|≦Tsᵥₐₗᵤₑ Equation 16

In Equation 16, Acc refers to an acceleration, and a_{g} refers to a gravitational acceleration.

In other words, when a value of difference between the acceleration Acc and gravitational acceleration a_{g} is in a critical range as defined by Equation 16, it is determined that the sensors are stationary or in a state of having a constant velocity. By contrast, when a value of the difference between the acceleration Acc and the gravitational acceleration a_{g} is outside the critical range of Equation 16, it is determined that the sensors are in a moving state. According to an embodiment, a magnitude of the threshold value Tsᵥₐₗᵤₑ is chosen to fall in the range of approximately 0.1 to 0.7 m/s².

The threshold value and the difference between the Acc value and gravitational acceleration 9.8 m/seĉ2 are compared as a reference value to determine whether the magnitude of the acceleration component is over the predetermined value. For example, assuming that the threshold value is 0.3 m/s², when the magnitude of the acceleration component is less than 0.3 m/s², the sensors are determined to be in a stationary state. If the magnitude of the acceleration component is greater than 0.3 m/s², the magnitude of acceleration component is more than 0.3 m/s², and is therefore determined to be in a moving state.

When the difference between the Acc value and a gravitational acceleration of 9.8 m/seĉ2 is within a predetermined range, the inclination angle is acquired as expressed in the aforementioned Equation 12 and Equation 14. However, if the acceleration is outside of the predetermined range, the sensors are determined to be in a moving state. In other words, in such a moving state, the sensors experience a state of acceleration and deceleration.

However, the aforementioned values, such as a specific threshold candidate, are merely examples used to predetermine a threshold value in an embodiment, and thus other values are applicable in other embodiments. However, if the threshold value is set to have too low a value, operation requires renewal of the inclination angle frequently as a result, causing instability in the system. If the threshold value is set to have too large a value, the calculation time for the inclination angle is possibly delayed, interfering with successful operation. In addition, when a value that is too larger is applied, an inclination angle with a low accuracy is calculated due to the effects of linear acceleration.

Accordingly, a fixed value or a variance mean value with respect to a calculated average value of the measured acceleration vector is possibly applied as the threshold value. Such an example is illustrated further according to the following discussion of an embodiment.

Second, determining a moving state considers a comparison of moving average value of the measured acceleration in an embodiment.

According to an embodiment, in step S25, when the difference between a moving average value of a number N of acceleration vectors that are measured for a sufficient period of time and a gravitational acceleration value is under a threshold value Tsvalue, it is determined that the sensors are in a stationary state. Herein, the moving average value of the number N of acceleration vectors is acquired as expressed in Equation 17, as follows:

$${Acc}_{mean} = \frac{{\sum }_{i = 1}^{N} ‖ {Acc}_{i} ‖}{N} \qquad Equation 17$$

In Equation 17, Accₘₑₐₙ refers to a moving average value, and each Accᵢ refers to an i^{th} acceleration vector, given by

∥Accᵢ∥=\sqrt{Aₓ_{ᵢ}²+A_{y}_{ᵢ}²+Aₓ_{ᵢ}²}.

The Accₘₑₐₙ value is possibly used instead of the original Acc that is used in Equation 16. In other words, according to an embodiment, Accₘₑₐₙ refers to a moving average value of a number N of acceleration vectors that is calculated as expressed in the Equation 17, and is able to be used as a replacement for the Acc value in Equation 16, such that the new criterion for whether a moving state is occurring is found based on the comparison (|∥Accₘₑₐₙ∥−a_{g}|)≦Tsᵥₐₗᵤₑ.

Accordingly, the sensor coordination system or magnetic sensor 10 is determined as being in a stationary state when Tsᵥₐₗᵤₑ is within the predetermined threshold value. The sensor coordination system is determined as being in a moving state when Tsᵥₐₗᵤₑ is outside the predetermined threshold range according to the modified Equation 16.

Third, determining a moving state includes comparison of a moving average value of the measured acceleration vector in an embodiment.

According to an embodiment, in S25, the threshold value Tsᵥₐₗᵤₑ is applied using a variance value of the most recently measured number N of acceleration vectors, as an alternative to other embodiments. In particular, in an embodiment, the variance value is acquired as expressed in Equation 18 as follows.

$${σ}_{Acc} = \sqrt{\frac{{\sum }_{i = 1}^{N} {( ‖ {Acc}_{i} ‖ - {Acc}_{mean} )}^{2}}{N}} \qquad Equation 18$$

In Equation 18, σ_{Acc} value refers to a variance value of acceleration vector, Accᵢ refers to an i^{th} acceleration vector and Accₘₑₐₙ refers to a moving average value of a number N of acceleration vectors.

The ACCₘₑₐₙ is able to be acquired as expressed in Equation 17. A method for calculating an inclination angle of a magnetic field according to the embodiments calculates horizontal inclination information regarding the measured magnetic field using an accelerometer and a measured result of a magnetometer.

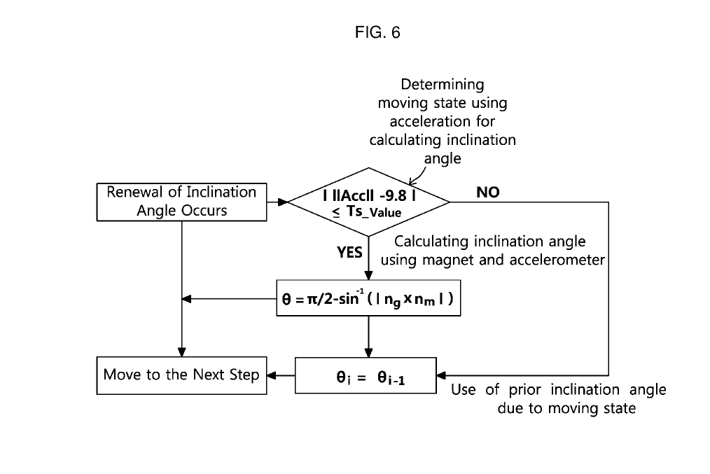

FIG. 6 illustrates a flowchart of a method for calculating an inclination angle under the premise that the method of calculating an inclination angle operates based on method steps illustrated in a flowchart.

Referring to FIG. 6, not only Equation 12 but also Equation 14 are used as equations used for calculating the inclination angle. In other words, when a value of a difference between the Acc value and a gravitational acceleration 9.8 m/seĉ2 is within a predetermined range, the inclination angle is acquired as expressed in the aforementioned Equations 12 and 14. However, if the acceleration Acc does not fall within a predetermined range of difference form the gravitational acceleration, the accelerometer is determined as being in a moving state. In other words, the accelerometer is determined to be in a situation of acceleration and deceleration. In this example, prior inclination values are used because the accelerometer is determined to be in a moving state.

Subsequently, an apparatus for calculating the inclination angle of the magnetic field using the method for calculating the inclination angle of the magnetic field is discussed further.

FIG. 7 illustrates a diagram of an apparatus for calculating the inclination angle of the geomagnetic force according to an embodiment.

As illustrated in the embodiment of FIG. 7, the apparatus for calculating the inclination angle of a magnetic line of force 1 according to an embodiment includes a magnetic sensor 10 configured to measure the magnetic field vector information nₘ, an acceleration sensor 20 configured to measure an acceleration vector information n_{g}, a horizontal inclination calculating unit or horizontal inclination calculator 30 configured to calculated an inclination angle of the magnetic line of force using the magnetic field vector information nₘ and acceleration vector information n_{g}.

Preferably, the apparatus for calculating the inclination angle of the magnetic line of force 1 also includes a moving state determining unit or moving state determiner 25 using the measured acceleration vector information through the acceleration sensor 20, and the apparatus for calculating the inclination angle of the magnetic line of force 1 accordingly operates the inclination angle calculation of the inclination angle calculator 30 only when determined to be in a stationary state through use of the moving state determiner 25.

Herein, the magnetic sensor 10 performs step S10 of FIG. 2, the acceleration sensor 20 performs step S20, and the inclination angle calculator 30 performs step S30. Further, the moving state determiner 25 performs step S25 of FIG. 2.

Respective modules of the apparatus for calculating the inclination angle of the magnetic line of force 1 according to FIG. 7 perform respective steps that are illustrated in FIG. 2 and a detailed discussion is omitted as details of such an embodiment are as aforementioned.

The apparatuses, units, modules, devices, and other components illustrated in FIGS. 1-7 that perform the operations described herein with respect to FIGS. 1-7 are implemented by hardware components. Examples of hardware components include controllers, sensors, generators, drivers, memories, comparators, arithmetic logic units, adders, subtractors, multipliers, dividers, integrators, and any other electronic components known to one of ordinary skill in the art. In one example, the hardware components are implemented by computing hardware, for example, by one or more processors or computers. A processor or computer is implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices known to one of ordinary skill in the art that is capable of responding to and executing instructions in a defined manner to achieve a desired result. In one example, a processor or computer includes, or is connected to, one or more memories storing instructions or software that are executed by the processor or computer. Hardware components implemented by a processor or computer execute instructions or software, such as an operating system (OS) and one or more software applications that run on the OS, to perform the operations described herein with respect to FIGS. 1-7. The hardware components also access, manipulate, process, create, and store data in response to execution of the instructions or software. For simplicity, the singular term “processor” or “computer” may be used in the description of the examples described herein, but in other examples multiple processors or computers are used, or a processor or computer includes multiple processing elements, or multiple types of processing elements, or both. In one example, a hardware component includes multiple processors, and in another example, a hardware component includes a processor and a controller. A hardware component has any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-7 that perform the operations described herein with respect to FIGS. 1-7 are performed by a processor or a computer as described above executing instructions or software to perform the operations described herein.

Instructions or software to control a processor or computer to implement the hardware components and perform the methods as described above are written as computer programs, code segments, instructions or any combination thereof, for individually or collectively instructing or configuring the processor or computer to operate as a machine or special-purpose computer to perform the operations performed by the hardware components and the methods as described above. In one example, the instructions or software include machine code that is directly executed by the processor or computer, such as machine code produced by a compiler. In another example, the instructions or software include higher-level code that is executed by the processor or computer using an interpreter. Programmers of ordinary skill in the art can readily write the instructions or software based on the block diagrams and the flow charts illustrated in the drawings and the corresponding descriptions in the specification, which disclose algorithms for performing the operations performed by the hardware components and the methods as described above.

The instructions or software to control a processor or computer to implement the hardware components and perform the methods as described above, and any associated data, data files, and data structures, are recorded, stored, or fixed in or on one or more non-transitory computer-readable storage media. Examples of a non-transitory computer-readable storage medium include read-only memory (ROM), random-access memory (RAM), flash memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, magnetic tapes, floppy disks, magneto-optical data storage devices, optical data storage devices, hard disks, solid-state disks, and any device known to one of ordinary skill in the art that is capable of storing the instructions or software and any associated data, data files, and data structures in a non-transitory manner and providing the instructions or software and any associated data, data files, and data structures to a processor or computer so that the processor or computer can execute the instructions. In one example, the instructions or software and any associated data, data files, and data structures are distributed over network-coupled computer systems so that the instructions and software and any associated data, data files, and data structures are stored, accessed, and executed in a distributed fashion by the processor or computer.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A method for calculating an angle of inclination of a magnetic field in a sensor coordination system, comprising:
measuring a magnetic field vector using a magnetometer;
measuring an acceleration vector using an accelerometer;
determining whether the sensor coordination system is in a moving state or a stationary state using the acceleration vector; and
calculating the inclination angle of the magnetic field using the magnetic field vector and the acceleration vector, in response to the sensor coordinate system being determined to be in the stationary state.

2. The method for calculating the angle of inclination of the magnetic field of claim 1, wherein the acceleration vector comprises a gravitational acceleration component and a linear acceleration component.

3. The method for calculating the angle of inclination of the magnetic field in a sensor coordination system of claim 1, wherein the sensor coordination system is determined to be in the stationary state in response to a following Equation being satisfied:

|∥Acc∥−a_{g}|≦Tsᵥₐₗᵤₑ,
wherein a_{g}, Acc and Tsᵥₐₗᵤₑ denote a gravitational acceleration value, a sensed acceleration vector, and a threshold value, respectively.

4. The method for calculating the angle of inclination of the magnetic field in a sensor coordination system of claim 3, wherein the acceleration vector has as its value a moving average value vector that is a moving average value regarding a size value of a number N of acceleration vectors according to a following Equation:
$${Acc}_{mean} = \frac{{\sum }_{i = 1}^{N} ‖ {Acc}_{i} ‖}{N} ,$$
wherein Accₘₑₐₙ is the moving average value vector and each Accᵢ is an i^{th} acceleration vector.

5. The method for calculating the angle of inclination of the magnetic field in a sensor coordination system of claim 3, wherein the threshold value is a fixed value or a variance value regarding a number N of latest measured acceleration vectors that is calculated according to a following Equation:
$${σ}_{Acc} = \sqrt{\frac{{\sum }_{i = 1}^{N} {( ‖ {Acc}_{i} ‖ - {Acc}_{mean} )}^{2}}{N}} ,$$
wherein σ_{Acc} is the variance value and each Accᵢ is an i^{th} acceleration vector.

6. The method for calculating the angle of inclination of the magnetic field in a sensor coordination system of claim 1, wherein the inclination angle of the magnetic field is calculated by a following Equation:
θ=π/2−sin⁻¹(|n_{g}×nₘ|),
wherein θ denotes the angle of inclination of the magnetic field, nₘ denotes the magnetic field vector, and n_{g} denotes the acceleration vector.

7. The method for calculating the angle of inclination of the magnetic field in a sensor coordination system of claim 1, wherein the inclination angle of the magnetic field is calculated by a following Equation:
θ=π/2−cos⁻¹(n_{g}·nₘ),
wherein θ denotes the angle of inclination of the magnetic field, nₘ denotes the magnetic field vector, and n_{g} denotes the acceleration vector.

8. The method for calculating the angle of inclination of the magnetic field in a sensor coordination system of claim 1, wherein the sensor coordination system comprises the magnetometer and the accelerometer.

9. The method for calculating the angle of inclination of the magnetic field in a sensor coordination system of claim 1, further comprising using a previously calculated inclination angle of the magnetic field as an estimate of the inclination angle of the magnetic field, in response to the sensor coordinate system being determined to be in the moving state.

10. An apparatus for calculating an angle of inclination of a magnetic field comprising:
a magnetic sensor configured to measure a magnetic sensor vector;
an accelerometer sensor configured to measure an acceleration vector;
a moving state determiner configured to determine whether the apparatus is in a moving state or a stationary state using the acceleration vector; and
an inclination angle calculator configured to calculate the inclination angle of the magnetic field using the magnetic vector and the acceleration vector, in response to determining that the apparatus is in a stationary state.

11. The apparatus for calculating the angle of inclination of the magnetic field of claim 10, wherein the acceleration vector comprises a gravitational acceleration component and a linear acceleration component.

12. The apparatus for calculating the angle of inclination of the magnetic field of claim 10, wherein the moving state determiner is configured to determine the stationary state in response to a following equation being satisfied:

|∥Acc∥−a_{g}|≦Tsᵥₐₗᵤₑ,
wherein a_{g}, Acc and Tsᵥₐₗᵤₑ denote a gravitational acceleration value, a sensed acceleration vector and a threshold value, respectively.

13. The apparatus for calculating the angle of inclination of the magnetic field of claim 12, wherein the acceleration vector has as its value a moving average value vector that is a moving average value regarding a size value of a number N of acceleration vectors according to a following Equation:
$${Acc}_{mean} = \frac{{\sum }_{i = 1}^{N} ‖ {Acc}_{i} ‖}{N} ,$$
wherein Accₘₑₐₙ is the moving average value vector and each Accᵢ is an i^{th} acceleration vector.

14. The apparatus for calculating the angle of inclination of the magnetic field of claim 12, wherein the threshold value is a fixed value or a variance regarding a number N of latest measured acceleration vectors that is calculated according to the following Equation:
$${σ}_{Acc} = \sqrt{\frac{{\sum }_{i = 1}^{N} {( ‖ {Acc}_{i} ‖ - {Acc}_{mean} )}^{2}}{N}} ,$$
wherein σ_{Acc} is the variance value and each Accᵢ is an i^{th} acceleration vector.

15. The apparatus for calculating the angle of inclination of the magnetic field of claim 10, wherein the inclination angle of magnetic field is calculated using the following equation:
θ=π/2−sin⁻¹(|n_{g}×nₘ|),
wherein θ denotes the angle of inclination of the magnetic field, nₘ denotes the magnetic field vector, and n_{g} denotes the acceleration vector.

16. The apparatus for calculating the angle of inclination of the magnetic field of claim 10, wherein the inclination angle of magnetic field is calculated using the following equation:
θ=π/2−cos⁻¹(n_{g}·nₘ),
wherein θ denotes the angle of inclination of the magnetic field, nₘ denotes the magnetic field vector, and n_{g} denotes the acceleration vector.

17. The apparatus for calculating the angle of inclination of the magnetic field of claim 10, wherein the inclination calculator uses a previously calculated inclination angle of the magnetic field as an estimate of the inclination angle of the magnetic field, in response to determining that the apparatus is in the moving state.
